(19) United States
(12) Patent Application Publication
(10) Pub. No.: US 2016/0350009 A1
(43) Pub. Date: Dec. 1, 2016

(54) BUFFERING DATA TO BE WRITTEN TO AN ARRAY OF NON-VOLATILE STORAGE DEVICES

(71) Applicant: Pure Storage, Inc., Mountain View, CA (US)

(72) Inventors: WILLIAM P. CERRETA, SAN MATEO, CA (US); JOHN COLGROVE, LOS ALTOS, CA (US); PETER E. KIRKPATRICK, MOUNTAIN VIEW, CA (US)

(21) Appl. No.: 14/725,278

(22) Filed: May 29, 2015

(51) Int. Cl. G06F 3/06; G11C 7/10; G11C 14/00

(52) U.S. Cl. CPC G06F 3/0619; G11C 14/0018; G06F 3/0688; G06F 3/0656; G11C 7/1072

(57) ABSTRACT

Buffering data to be written to an array of non-volatile storage devices, including: receiving a request to write data to the array of non-volatile storage devices; sending, to a non-volatile random access memory (‘NVRAM’) device, an instruction to write the data to dynamic random access memory (‘DRAM’) in the NVRAM device, the DRAM configured to receive power from a primary power source, the DRAM further configured to receive power from a backup power source in response to the primary power source failing; and writing the data to the DRAM in the NVRAM device.

### BACKGROUND

Field of Technology

The field of technology is methods, apparatuses, and products for buffering data to be written to an array of non-volatile storage devices.

Description of Related Art

Enterprise storage systems can provide large amounts of computer storage to modern enterprises. When users of the enterprise storage system issue requests to write data to the enterprise storage system, the users may experience poor write latencies as data must frequently be written to relatively slow, non-volatile memory such as a disk drive before the enterprise storage system acknowledges such requests.

### SUMMARY

Methods, apparatus, and products for buffering data to be written to an array of non-volatile storage devices, including: receiving a request to write data to the array of non-volatile storage devices; sending, to a non-volatile random access memory (‘NVRAM’) device, an instruction to write the data to dynamic random access memory (‘DRAM’) in the NVRAM device, the DRAM configured to receive power from a primary power source, the DRAM further configured to receive power from a backup power source in response to the primary power source failing; and writing the data to the DRAM in the NVRAM device.

The foregoing and other objects, features and advantages of the invention will be apparent from the following more particular descriptions of example embodiments of the invention as illustrated in the accompanying drawings wherein like reference numbers generally represent like parts of example embodiments of the invention.

### BRIEF DESCRIPTION OF THE DRAWINGS

FIG. 1 sets forth a block diagram of a system configured for buffering data to be written to an array of non-volatile storage devices according to embodiments of the present invention.

FIG. 2 sets forth a block diagram of a storage array controller useful in buffering data to be written to an array of non-volatile storage devices according to embodiments of the present invention.

FIG. 3 sets forth a block diagram illustrating an NVRAM device useful in buffering data to be written to an array of non-volatile storage devices according to embodiments of the present invention.

FIG. 4 sets forth a flow chart illustrating an example method of buffering data to be written to an array of non-volatile storage devices according to embodiments of the present invention.

### DETAILED DESCRIPTION OF EXAMPLE EMBODIMENTS

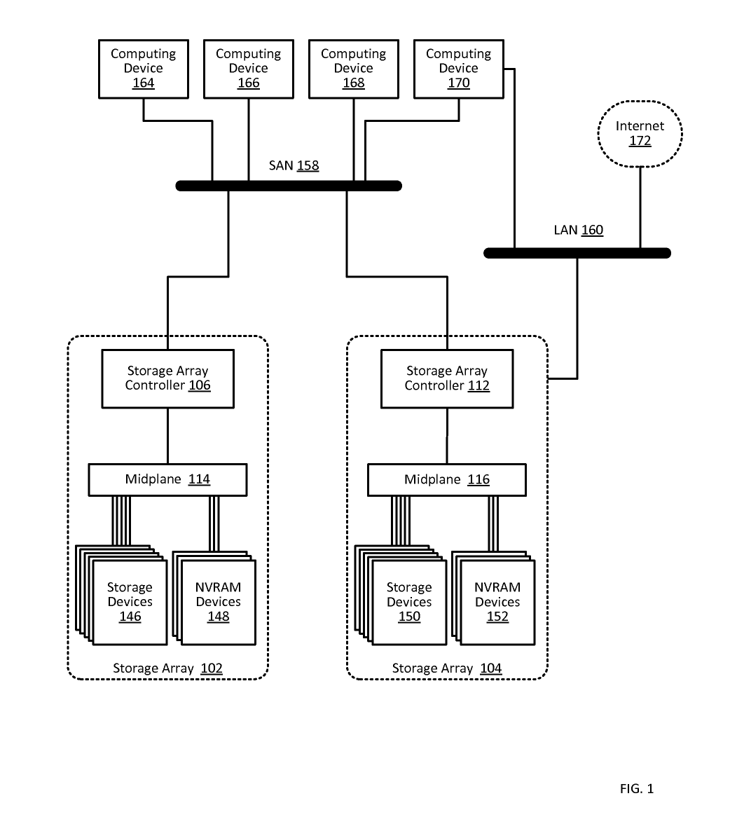

Example methods, apparatuses, and products for buffering data to be written to an array of non-volatile storage devices in accordance with the present invention are described with reference to the accompanying drawings, beginning with FIG. 1.

FIG. 1 sets forth a block diagram of a system configured for buffering data to be written to an array of non-volatile storage devices according to embodiments of the present invention. The system of FIG. 1 includes a plurality of computing devices (164, 166, 168, 170). Such computing devices may be implemented in a number of different ways. For example, a computing device may be a server in a data center, a workstation, a personal computer, a notebook, or the like.

The computing devices (164, 166, 168, 170) in the example of FIG. 1 are coupled for data communications to one or more storage arrays (102, 104) through a storage area network (‘SAN’) (158) as well as a local area network (160) (LAM). The SAN (158) may be implemented with a variety of data communications fabrics, devices, and protocols. Example fabrics for such a SAN (158) may include Fibre Channel, Ethernet, Infiniband, Serial Attached SCSI (‘SAS’), and the like. Example data communications protocols for use in such a SAN (158) may include Advanced Technology Attachment (‘ATA’), Fibre Channel Protocol, SCSI, iSCSI, HyperSCSI, and others. Readers of skill in the art will recognize that a SAN is just one of many possible data communications couplings which may be implemented between a computing device (164, 166, 168, 170) and a storage array (102, 104), and readers will further appreciate that any other data communications coupling is well within the scope of embodiments of the present invention.

The local area network (160) of FIG. 1 may also be implemented with a variety of fabrics and protocols. Examples of such fabrics include Ethernet (802.3), wireless (802.11), and the like. Examples of such data communications protocols include Transmission Control Protocol (‘TCP’), User Datagram Protocol (‘UDP’), Internet Protocol (IP), HyperText Transfer Protocol (‘HTTP’), Wireless Access Protocol (‘WAP’), Handheld Device Transport Protocol (‘HDTP’), Session Initiation Protocol (SIP), Real Time Protocol (‘RTP’), and so on.

The example storage arrays (102, 104) of FIG. 1 provide persistent data storage for the computing devices (164, 166, 168, 170). Each storage array (102, 104) depicted in FIG. 1 includes one or more storage array controllers (106, 112). Each storage array controller (106, 112) may be embodied as a module of automated computing machinery comprising computer hardware, computer software, or a combination of computer hardware and software. The storage array controllers (106, 112) may be configured to carry out various storage-related tasks. Such tasks may include writing data received from the one or more of the computing devices (164, 166, 168, 170) to storage, erasing data from storage, retrieving data from storage to provide the data to one or more of the computing devices (164, 166, 168, 170), monitoring and reporting of disk utilization and performance, performing Redundant Array of Independent Drives (‘RAID’) or RAID-like data redundancy operations, compressing data, encrypting data, and so on.

Each storage array controller (106, 112) may be implemented in a variety of ways, including as an Field Programmable Gate Array (‘FPGA’), a Programmable Logic Chip (‘PLC’), an Application Specific Integrated Circuit (‘ASIC’), or computing device that includes discrete components such as a central processing unit, computer memory, and various adapters. Each storage array controller (106, 112) may include, for example, a data communications adapter configured to support communications via the SAN (158) and the LAN (160). Although only one of the storage array controllers (112) in the example of FIG. 1 is depicted as being coupled to the LAN (160) for data communications, readers will appreciate that both storage array controllers (106, 112) may be independently coupled to the LAN (160). Each storage array controller (106, 112) may also include, for example, an I/O controller or the like that couples the storage array controller (106, 112) for data communications, through a midplane (114), to a number of storage devices (146, 150), and a number of NVRAM devices (148, 152).

Each NVRAM device (148, 152) may be configured to receive, from the storage array controller (106, 112), data to be stored in the storage devices (146). Such data may originate from any one of the computing devices (164, 166, 168, 170). In the example of FIG. 1, writing data to the NVRAM device may be carried out more quickly than writing data to the storage device. The storage array controller (106, 112) may be configured to effectively utilize the NVRAM devices (148, 152) as a quickly accessible buffer for data destined to be written to the storage devices (146, 150). In this way, the latency of write requests may be significantly improved relative to a system in which the storage array controller writes data directly to the storage devices (146, 150).

The NVRAM devices may be implemented with computer memory in the form of high bandwidth, low latency DRAM. In such an embodiment, each NVRAM device is referred to as ‘non-volatile’ because each NVRAM device may receive or include a unique power source that maintains the state of the DRAM after main power loss to the NVRAM device (148, 152). Such a power source may be a battery, one or more capacitors, or the like. During the power loss, the NVRAM device (148, 152) may be configured to write the contents of the DRAM to a persistent storage, such as flash memory contained within the NVRAM device (148, 152). Such flash memory that is contained within the NVRAM device (148, 152) may be embodied, for example, as one or more non-volatile dual-inline memory modules (‘NVDIMMs’).

A ‘storage device’ as the term is used in this specification refers to any device configured to record data persistently. The term ‘persistently’ as used here refers to a device's ability to maintain recorded data after loss of a power source. Examples of storage devices may include mechanical, spinning hard disk drives, solid-state drives (“Flash drives”), and the like.

The storage array controllers (106, 112) of FIG. 1 may be useful for buffering data to be written to an array of non-volatile storage devices (146, 150) according to embodiments of the present invention. The storage array controllers (106, 112) may be useful for buffering data to be written to an array of non-volatile storage devices (146, 150) by initially receiving a request to write data to the array (102, 104) of non-volatile storage devices (146, 150). The request to write data to the array (102, 104) of non-volatile storage devices (146, 150) may be received from one of the computing devices (164, 166, 168, 170) via the SAN (158), via the LAN (160), or via another data communications link between the computing devices (164, 166, 168, 170) and the storage array controllers (106, 112).

The storage array controllers (106, 112) may be further useful for buffering data to be written to an array of non-volatile storage devices (146, 150) by sending, to an NVRAM device (148, 152), an instruction to write the data to DRAM in the NVRAM device (148, 152). As described above, each NVRAM device (148, 152) can include DRAM that may be configured to receive power from a primary power source and further configured to receive power from a backup power source in response to the primary power source failing. In such a way, power loss to the NVRAM device (148, 152) will not cause data stored in DRAM of the NVRAM device (148, 152) to be lost. In response to the storage array controllers (106, 112) sending an instruction to write the data to DRAM in the NVRAM device (148, 152), a controller within the NVRAM device (148, 152) may write the data to the DRAM in the NVRAM device (148, 152).

The arrangement of computing devices, storage arrays, networks, and other devices making up the example system illustrated in FIG. 1 are for explanation, not for limitation. Systems useful according to various embodiments of the present invention may include different configurations of servers, routers, switches, computing devices, and network architectures, not shown in FIG. 1, as will occur to those of skill in the art.

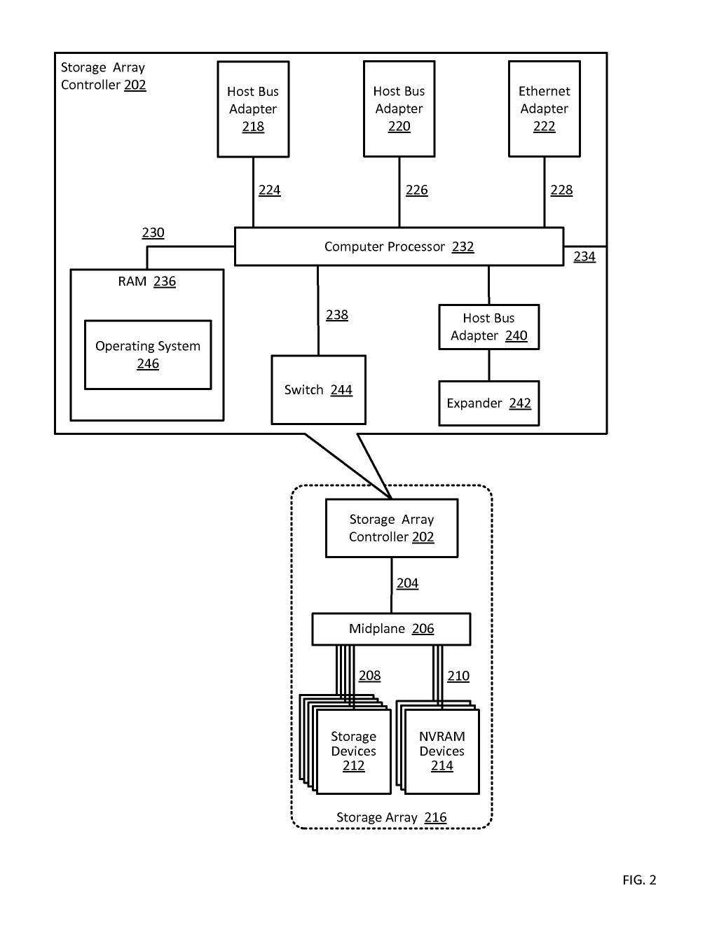

Buffering data to be written to an array of non-volatile storage devices in accordance with embodiments of the present invention is generally implemented with computers. In the system of FIG. 1, for example, all the computing devices (164, 166, 168, 170) and storage controllers (106, 112) may be implemented, to some extent at least, as computers. For further explanation, FIG. 2 therefore sets forth a block diagram of a storage array controller (202) useful for buffering data to be written to an array of non-volatile storage devices according to embodiments of the present invention.

The storage array controller (202) of FIG. 2 is similar to the storage array controllers depicted in FIG. 1. For example, the storage array controller (202) of FIG. 2 is also communicatively coupled, via a midplane (206), to one or more storage devices (212) and also to one or more NVRAM devices (214) that are included as part of a storage array (216). The storage array controller (202) may be coupled to the midplane (206) via one or more data communications links (204) and the midplane (206) may be coupled to the storage devices (212) and the NVRAM devices (214) via one or more data communications links (208, 210). The data communications links (204, 208, 210) of FIG. 2 may be embodied, for example, as Peripheral Component Interconnect Express (‘PCIe’) bus.

The storage array controller (202) of FIG. 2 includes at least one computer processor (232) or ‘CPU’ as well as RAM (236). The computer processor (232) may be connected to the RAM (236) via a data communications link (230), which may be embodied as a high speed memory bus such as a Double-Data Rate 4 (‘DDR4’) bus.

Stored in RAM (214) is an operating system (246). Examples of operating systems useful in storage array controllers (202) configured for buffering data to be written to an array of non-volatile storage devices according to embodiments of the present invention include UNIX™, Linux™, Microsoft Windows™, and others as will occur to those of skill in the art. The operating system (246) in the example of FIG. 2 is shown in RAM (168), but many components of such software may be stored in non-volatile memory such as a disk drive, an SSD, and so on.

The storage array controller (202) of FIG. 2 also includes a plurality of host bus adapters (218, 220, 222) that are coupled to the processor (232) via a data communications link (224, 226, 228). Each host bus adapter (218, 220, 222) may be embodied as a module of computer hardware that connects the host system (i.e., the storage array controller) to other network and storage devices. Each host bus adapter (218, 220, 222) of FIG. 2 may be embodied, for example, as a Fibre Channel adapter that enables the storage array controller (202) to connect to a SAN, as an Ethernet adapter that enables the storage array controller (202) to connect to a LAN, and so on. Each host bus adapter (218, 220, 222) may be coupled to the computer processor (232) via a data communications link (224, 226, 228) such as, for example, a PCIe bus.

The storage array controller (202) of FIG. 2 also includes a switch (244) that is coupled to the computer processor (232) via a data communications link (238). The switch (244) of FIG. 2 may be embodied as a computer hardware device that can create multiple ports out of a single port, thereby enabling multiple devices to share what was initially a single port. The switch (244) of FIG. 2 may be embodied, for example, as a PCIe switch that is coupled to a PCIe bus (238) and presents multiple PCIe connection points to the midplane (206).

The storage array controller (202) of FIG. 2 also includes a host bus adapter (240) that is coupled to an expander (242). The expander (242) depicted in FIG. 2 may be embodied, for example, as a module of computer hardware utilized to attach a host system to a larger number of storage devices than would be possible without the expander (242). The expander (242) depicted in FIG. 2 may be embodied, for example, as a SAS expander utilized to enable the host bus adapter (240) to attach to storage devices in an embodiment where the host bus adapter (240) is embodied as a SAS controller. In alternative embodiment, the combination of a host bus adapter (240) and expander (242) may be replaced by a PCIe switch as described in the preceding paragraph.

The storage array controller (202) of FIG. 2 also includes a data communications link (234) for coupling the storage array controller (202) to other storage array controllers. Such a data communications link (234) may be embodied, for example, as a PCIe Non-Transparent Bridge (‘NTB’), a QuickPath Interconnect (‘QPI’) interconnect, and so on. Readers will appreciate, however, that such a data communications link (234) may be embodied using other interconnects and protocols in accordance with embodiments described herein.

Readers will recognize that these components, protocols, adapters, and architectures are for illustration only, not limitation. Such a storage array controller may be implemented in a variety of different ways, each of which is well within the scope of the present invention.

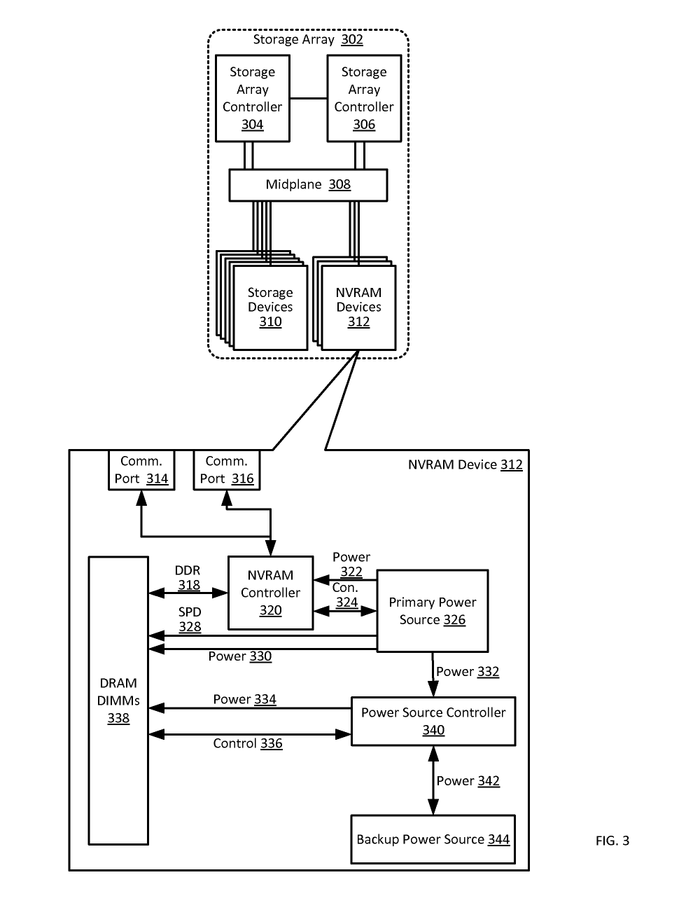

For further explanation, FIG. 3 sets forth a block diagram illustrating an NVRAM device (312) useful in buffering data to be written to an array of non-volatile storage devices according to embodiments of the present invention. The NVRAM device (312) depicted in FIG. 3 is similar to the NVRAM devices depicted in FIG. 1 and FIG. 2. The NVRAM device (312) may be included in a storage array (302) that includes a plurality of storage array controllers (304, 306) that are communicatively coupled to a plurality of storage devices (310) and also communicatively coupled to a plurality of NVRAM devices (312) via a midplane (308).

The NVRAM device (312) depicted in FIG. 3 includes two data communications ports (314, 316). The data communications ports (314, 316) of FIG. 3 may be embodied, for example, as computer hardware for communicatively coupling the NVRAM device (312) to a storage array controller (304, 306) via the midplane (308). For example, the NVRAM device (312) may be communicatively coupled to the first storage array controller (304) via a first data communications port (314) and the NVRAM device (312) may also be communicatively coupled to the second storage array controller (306) via a second data communications port (316). Although the NVRAM device (312) depicted in FIG. 3 includes two data communications ports (314, 316), readers will appreciate that NVRAM devices useful for buffering data to be written to an array of non-volatile storage devices may include only one data communications port or, alternatively, additional data communications ports not depicted in FIG. 3.

The NVRAM device (312) depicted in FIG. 3 also includes an NVRAM controller (320). The NVRAM controller (320) depicted in FIG. 3 may be embodied, for example, as computer hardware for receiving memory access requests (e.g., a request to write data to memory in the NVRAM device) via the data communications ports (314, 316) and servicing such memory access requests. The NVRAM controller (320) depicted in FIG. 3 may be embodied, for example, as an ASIC, as a microcontroller, and so on. The NVRAM controller (320) depicted in FIG. 3 may be communicatively coupled the data communications ports (314, 316), for example, via a PCIe data communications bus.

The NVRAM device (312) depicted in FIG. 3 also includes a plurality of DRAM memory modules, embodied in FIG. 3 as DRAM dual in-line memory modules (‘DIMMs’) (338). The DRAM DIMMs (338) depicted in FIG. 3 may be coupled to the NVRAM controller (320) via a memory bus such as a DDR (318) memory bus such that the NVRAM controller (320) can be configured to write data to the DRAM DIMMs (338) via the DDR (318) memory bus.

The NVRAM device (312) depicted in FIG. 3 also includes a primary power source (326). The primary power source (326) may be embodied as computer hardware for providing electrical power to the computing components that are within the NVRAM device (312). The primary power source (326) may be embodied, for example, as a switched-mode power supply that supplies electric energy to an electrical load by converting alternating current (‘AC’) power from a mains supply to a direct current (‘DC’) power, as a DC-to-DC converter that converts a source of direct current (DC) from one voltage level to another, and so on. The primary power source (326) of FIG. 3 is coupled to the NVRAM controller (320) via a power line (322) that the primary power source (326) can use to deliver power to the NVRAM controller (320). The primary power source (326) of FIG. 3 is also coupled to the DRAM DIMMs (338) via a power line (330) that the primary power source (326) can use to deliver power to the DRAM DIMMs (338). The primary power source (326) of FIG. 3 is also coupled to a power source controller (340) via a power line (332) that the primary power source (326) can use to deliver power to the power source controller (340). The primary power source (326) can monitor which components are receiving power through the use of one or more control lines (324), serial presence detect (‘SPD’) lines (328), or other mechanism for detecting the presence of a device and detecting that power is being provided to the device. Readers will appreciate that NVRAM devices useful for buffering data to be written to an array of non-volatile storage devices may include additional computing components not depicted in FIG. 3, each of which may also receive power from the primary power source (326).

The NVRAM device (312) depicted in FIG. 3 also includes a backup power source (344). The backup power source (344) depicted in FIG. 3 represents a power source capable of providing power to the DRAM DIMMs (338) in the event that the primary power source (326) fails. In such a way, the DRAM DIMMs (338) may effectively serve as non-volatile memory, as a failure of the primary power source (326) will not cause the contents of the DRAM DIMMs (338) to be lost because the DRAM DIMMs (338) will continue to receive power from the backup power source (344). Such a backup power source (344) may be embodied, for example, as a supercapacitor.

The NVRAM device (312) depicted in FIG. 3 also includes a power source controller (340). The power source controller (340) depicted in FIG. 3 may be embodied as a module of computer hardware configured to identify a failure of the primary power source (326) and to cause power to be delivered to the DRAM DIMMs (338) from the backup power source (344). In such an example, power may be delivered to the DRAM DIMMs (338) from the backup power source (344) via a first power line (342) between the power source controller (340) and the backup power source (344), as well as a second power line (334) between the backup power source controller (340) and the DRAM DIMMs (338). The backup power source controller (340) depicted in FIG. 3 may be embodied, for example, as an analog circuit, an ASIC, a microcontroller, and so on. The power source controller (340) can monitor whether the DRAM DIMMs (338) have power through the use of one or more control lines (336) that may be coupled to the DRAM DIMMs (338), as well as one or more control lines that may be coupled to the primary power source (326). In such an example, by exchanging signals between the DRAM DIMMs (338), the primary power source (326), and the power source controller (340), the power source controller (340) may identify whether power is being provided to the DRAM DIMMs (338) by the primary power source (326).

In the example depicted in FIG. 3, the NVRAM controller (320) may be configured to receive, from a storage array controller (304, 306) via the one or more data communications ports (314, 316), an instruction to write data to the one or more DRAM DIMMs (338). Such an instruction may include, for example, the location at which to write the data, the data to be written to the DRAM DIMMs (338), the identity of the host that issued the instruction, the identity of a user associated with the instruction, or any other information needed to service the instruction. In the example depicted in FIG. 3, the NVRAM controller (320) may be further configured to write the data to the one or more DRAM DIMMs (338) in response to receiving such an instruction.

In the example depicted in FIG. 3, the NVRAM controller (320) may be further configured to send an acknowledgment indicating that the data has been written to the array (302) of non-volatile storage devices in response to writing the data to the one or more DRAM DIMMs (338). The NVRAM controller (320) may send the acknowledgment indicating that the data has been written to the array (302) of non-volatile storage devices in response to writing the data to the DRAM DIMMs (338) in the NVRAM device (312). Readers will appreciate that although some forms of DRAM DIMMs (338) are considered to be volatile memory, because the DRAM DIMMs (338) are backed by redundant power sources (326, 344), writing the data to the DRAM DIMMs (338) in the NVRAM device (312) may be treated the same as writing the data to traditional forms of non-volatile memory such as the storage devices (310). Furthermore, the DRAM DIMMs (338) in the NVRAM device (312) can include one or more NVDIMMs. As such, once the data has been written to the DRAM DIMMs (338) in the NVRAM device (312), an acknowledgement may be sent indicating that the data has been safely and persistently written to the array (302) of non-volatile storage devices.

In the example depicted in FIG. 3, the NVRAM controller (320) may be further configured to determine whether the primary power source (326) has failed. The NVRAM controller (320) may determine whether the primary power source (326) has failed, for example, by receiving a signal over the control line (324) indicating that the primary power source (326) has failed or is failing, by detecting a lack of power from the primary power source (326), and so on. In such an example, the NVRAM controller (320) may be coupled to the backup power source (344) or may have access to another source of power such that the NVRAM controller (320) can remain operational if the primary power source (326) does fail.

In the example depicted in FIG. 3, the NVRAM controller (320) may be further configured to initiate a transfer of data contained in the one or more DRAM DIMMs (338) to flash memory in the NVRAM device (312) in response to determining that the primary power source (326) has failed. The NVRAM controller (320) may initiate a transfer of data contained in the one or more DRAM DIMMs (338) to flash memory in the NVRAM device (312), for example, by signaling an NVDIMM to write the data contained in the one or more DRAM DIMMs (338) to flash memory on the NVDIMM.

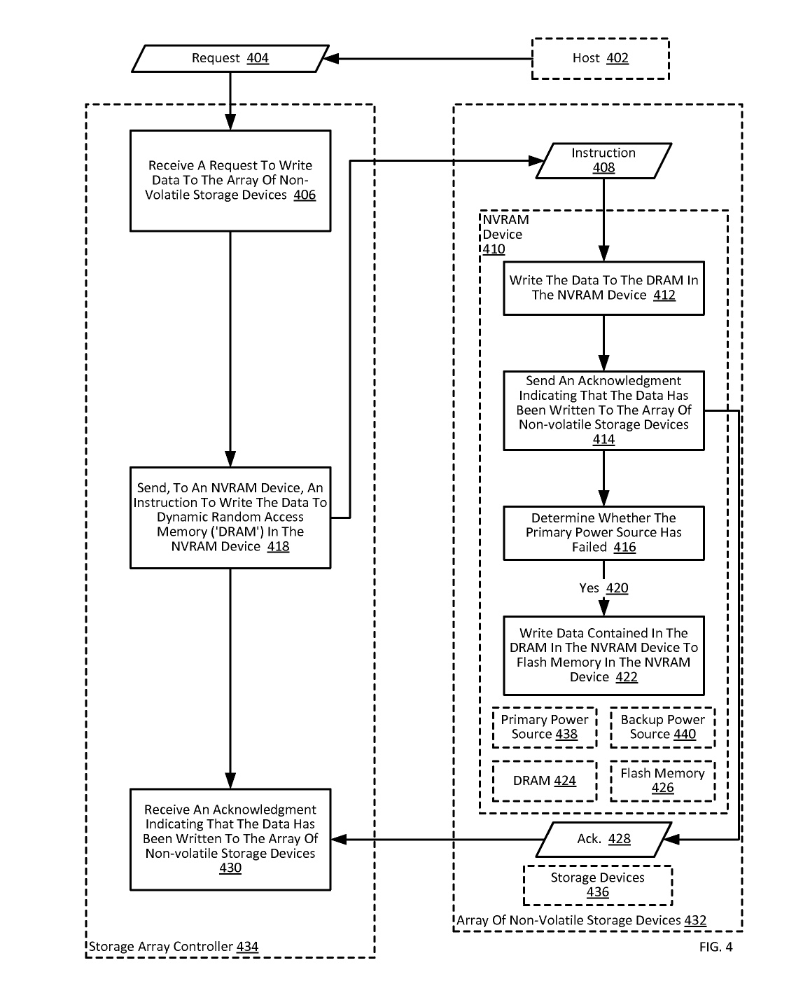

For further explanation, FIG. 4 sets forth a flow chart illustrating an example method of buffering data to be written to an array (432) of non-volatile storage devices according to embodiments of the present invention. The array (432) of non-volatile storage devices depicted in FIG. 4 may be similar to the arrays described above and depicted in FIGS. 1-3, as the array (432) of non-volatile storage devices depicted in FIG. 4 can include storage devices (436) such as SSDs as well as NVRAM devices (410). Although not illustrated in FIG. 4, the NVRAM device (410) can be similar to the NVRAM device depicted in FIG. 3, as the NVRAM device (410) can include a plurality of data communications ports. In such a way, NVRAM device (410) may be coupled to a first storage array controller via a first data communications port and the NVRAM device (410) may also be coupled to a second storage array controller via a second data communications port. In fact, readers will appreciate that the NVRAM device (410) may even include additional data communications ports for facilitating data communications with additional storage array controllers.

The example method depicted in FIG. 4 includes receiving (406) a request (404) to write data to the array (432) of non-volatile storage devices. The request (404) to write data to the array (432) of non-volatile storage devices may be embodied, for example, as a write instruction issued from a host (402) that is communicatively coupled to the storage array controller (434) via a SAN, a LAN, or some other data communications link. The request (404) to write data to the array (432) of non-volatile storage devices may include the data to be written to the array (432) of non-volatile storage devices, a reference to the data to be written to the array (432) of non-volatile storage devices, the identity of the host (402) that issued the request (404), the identity of a user associated with the request (404), or any other information needed to service the request (404).

The example method depicted in FIG. 4 also includes sending (418), to an NVRAM device (410), an instruction (408) to write the data to DRAM (424) in the NVRAM device (410). In the example method depicted in FIG. 4, the storage array controller (434) may send (418) an instruction (408) to write the data to DRAM (424) in the NVRAM device (410) over a data communication link between the storage array controller (434) and the NVRAM device (410). In response to the instruction (408) to write the data to DRAM (424) in the NVRAM device (410), the NVRAM device (410) may write (422) the data to the DRAM (424) in the NVRAM device (410).

Although not illustrated in FIG. 4, the DRAM (424) depicted in FIG. 4 may be similar to the DRAM depicted in FIG. 3, as the DRAM (424) depicted in FIG. 4 may also be configured to receive power from a primary power source (438) and further configured to receive power from a backup power source (440) in response to the primary power source (438) failing. Through the use of redundant power sources (438, 440), the DRAM (424) may effectively serve as non-volatile memory because a failure of the primary power source (438) will not cause the contents of the DRAM (424) to be lost, as the DRAM (424) will continue to receive power from the backup power source (440).

The example method depicted in FIG. 4 also includes sending (414) an acknowledgment (428) indicating that the data has been written to the array of non-volatile storage devices. The NVRAM device (410) may send (414) the acknowledgment (428) indicating that the data has been written to the array of non-volatile storage devices in response to writing (422) the data to the DRAM (424) in the NVRAM device (410). Readers will appreciate that although some forms of DRAM (424) are considered to be volatile memory, because the DRAM (424) depicted in FIG. 4 is backed by a redundant power source, writing (422) the data to the DRAM (424) in the NVRAM device (410) may be treated the same as writing the data to traditional forms of non-volatile memory such as the storage devices (436). Furthermore, the DRAM (424) in the NVRAM device (410) can include one or more NVDIMMs. As such, once the data has been written (422) to the DRAM (424) in the NVRAM device (410), an acknowledgement (428) may be sent indicating that the data has been safely and persistently written to the array of non-volatile storage devices.

The example method depicted in FIG. 4 also includes determining (416) whether the primary power source (438) has failed. In the example method depicted in FIG. 4, determining (416) whether the primary power source (438) has failed may be carried out through the use of a computer hardware device, such as the power source controller (340 of FIG. 3) described above, that is coupled to the primary power source (438) and configured to determine whether the primary power source (438) is outputting power.

The example method depicted in FIG. 4 also includes writing (422) data contained in the DRAM (424) in the NVRAM device (410) to flash memory (426) in the NVRAM device (410). In the example method depicted in FIG. 4, writing (422) data contained in the DRAM (424) in the NVRAM device (410) to flash memory (426) in the NVRAM device (410) is carried out in response to affirmatively (420) determining that the primary power source (438) has failed. Readers will appreciate that when the primary power source (438) has failed, the DRAM (424) is no longer backed by redundant power supplies. As such, data contained in the DRAM (424) may be written (422) to flash memory (426) in the NVRAM device (410) to ensure that no data loss occurs if the backup power source (440) subsequently fails. In embodiments where the power sources (438, 440) are different types of power sources (e.g., the primary power source (438) is a switched-mode power supply and the backup power source (440) is a supercapacitor), the primary power source (438) failing will not necessarily result in the backup power source (440) failing. For example, if the primary power source (438) fails because power is lost to a physical building where the primary power source (438) is located, the backup power source (440) will be unaffected.

Example embodiments of the present invention are described largely in the context of a fully functional computer system. It will be understood from the foregoing description that modifications and changes may be made in various embodiments of the present invention without departing from its true spirit. The descriptions in this specification are for purposes of illustration only and are not to be construed in a limiting sense. The scope of the present invention is limited only by the language of the following claims.

1. A method of buffering data to be written to an array of non-volatile storage devices in a multi-array system, the method comprising:
receiving, by a storage array controller in a first storage array, a request to write data to non-volatile storage devices in the first storage array;
sending, from the storage array controller in the first storage array to a non-volatile random access memory (‘NVRAM’) storage device in the first storage array, an instruction to write the data to dynamic random access memory (‘DRAM’) in the NVRAM storage device in the first storage array, wherein:
the DRAM is configured to receive power from a primary power source, and the DRAM is further configured to receive power from a backup power source in response to the primary power source failing;
the NVRAM storage device in the first storage array is available for exclusive use by one or more storage array controllers in the first storage array; and
the multi-array system includes a second storage array that includes a plurality of non-volatile storage devices and an NVRAM storage device in the second storage array, the NVRAM storage device in the second storage array available for exclusive use by one or more storage array controllers in the second storage array;
writing the data to the DRAM in the NVRAM storage device in the first storage array.

2. The method of claim 1 further comprising:
determining whether the primary power source has failed; and
responsive to determining that the primary power source has failed, writing data contained in the DRAM in the NVRAM storage device in the first storage array to flash memory in the NVRAM storage device in the first storage array.

3. The method of claim 1 wherein each NVRAM storage device includes a plurality of data communications ports, wherein:
the NVRAM storage device in the first storage array is coupled to a first storage array controller in the first storage array via a first data communications port and the NVRAM storage device in the first storage array is coupled to a second storage array controller in the first storage array via a second data communications port; and
the NVRAM storage device in the second storage array is coupled to a first storage array controller in the second storage array via a first data communications port and the NVRAM storage device in the second storage array is coupled to a second storage array controller in the second storage array via a second data communications port.

4. The method of claim 1 wherein the DRAM in the NVRAM storage device in the first storage array includes one or more non-volatile dual in-line memory modules (‘NVDIMMs’).

5. The method of claim 1 wherein the backup power source includes a supercapacitor.

6. The method of claim 1 further comprising responsive to writing the data to the DRAM in the NVRAM storage device in the first storage array, sending an acknowledgment indicating that the data has been written to the first storage array.

7. A system for buffering data to be written to an array of non-volatile storage devices in a multi-array system, the system configured to carry out the steps of:
receiving, by a storage array controller in a first storage array, a request to write data to non-volatile storage devices in the first storage array;
sending, from the storage array controller in the first storage array to a non-volatile random access memory (‘NVRAM’) storage device in the first storage array, an instruction to write the data to dynamic random access memory (‘DRAM’) in the NVRAM storage device in the first storage array, wherein:
the DRAM is configured to receive power from a primary power source, and the DRAM is further configured to receive power from a backup power source in response to the primary power source failing;
the NVRAM storage device in the first storage array is available for exclusive use by one or more storage array controllers in the first storage array; and
the multi-array system includes a second storage array that includes a plurality of non-volatile storage devices and an NVRAM storage device in the second storage array, the NVRAM storage device in the second storage array available for exclusive use by one or more storage array controllers in the second storage array;
writing the data to the DRAM in the NVRAM storage device in the first storage array.

8. The system of claim 7 further configured to carry out the steps of:
determining whether the primary power source has failed; and
responsive to determining that the primary power source has failed, writing data contained in the DRAM in the NVRAM storage device in the first storage array to flash memory in the NVRAM storage device in the first storage array.

9. The system of claim 7 wherein each NVRAM storage device includes a plurality of data communications ports, wherein:
the NVRAM storage device in the first storage array is coupled to a first storage array controller in the first storage array via a first data communications port and the NVRAM storage device in the first storage array is coupled to a second storage array controller in the first storage array via a second data communications port; and
the NVRAM storage device in the second storage array is coupled to a first storage array controller in the second storage array via a first data communications port and the NVRAM storage device in the second storage array is coupled to a second storage array controller in the second storage array via a second data communications port.

10. The system of claim 7 wherein the DRAM in the NVRAM storage device in the first storage array includes one or more non-volatile dual in-line memory modules (‘NVDIMMs’).

11. The system of claim 7 wherein the backup power source includes a supercapacitor.

12. The system of claim 7 further configured to carry out the step of, responsive to writing the data to the DRAM in the NVRAM storage device in the first storage array, sending an acknowledgment indicating that the data has been written to the first storage array.

13. A non-volatile random access memory (‘NVRAM’) storage device for buffering data to be written to an array of non-volatile storage devices, the NVRAM device including:
one or more data communications ports;
one or more dynamic random access memory (‘DRAM’) memory modules;
a primary power source configured to provide power to the DRAM memory modules;
a backup power source configured to provide power to the DRAM memory modules upon a failure of the primary power source, wherein the NVRAM storage device is included in a first storage array in a multi-array system, the multi-array system including second storage array that includes a plurality of non-volatile storage devices and an NVRAM storage device in the second storage array, the NVRAM storage device in the second storage array available for exclusive use by one or more storage array controllers in the second storage array; and
an NVRAM controller, the NVRAM controller configured to carry out the steps of:
receiving, from a storage array controller in the first storage array via the one or more data communications ports, an instruction to write data to the one or more DRAM memory modules; and
writing the data to the one or more DRAM memory modules.

14. The NVRAM storage device of claim 13 wherein the NVRAM storage device includes flash memory, and wherein the NVRAM controller is further configured to carry out the steps of:
determining whether the primary power source has failed; and
responsive to determining that the primary power source has failed, initiating a transfer of data contained in the one or more DRAM memory modules to flash memory in the NVRAM storage device.

15. The NVRAM storage device of claim 13 wherein the NVRAM storage device includes a plurality of data communications ports, wherein the NVRAM storage device is coupled to a first storage array controller in the first storage array via a first data communications port and the NVRAM storage device is coupled to a second storage array controller in the first storage array via a second data communications port.

16. The NVRAM storage device of claim 13 wherein the DRAM memory modules in the NVRAM storage device includes one or more non-volatile dual in-line memory modules (‘NVDIMMs’).

17. The NVRAM storage device of claim 13 wherein the backup power source includes a supercapacitor.

18. The NVRAM storage device of claim 13 wherein the NVRAM controller is further configured to carry out the step of, responsive to writing the data to the one or more DRAM memory modules, sending an acknowledgment indicating that the data has been written to the array of non-volatile storage devices.
